(19) United States
(12) Patent Application Publication
(10) Pub. No.: US 2025/0257576 A1
(43) Pub. Date: Aug. 14, 2025

(54) FLOOR ASSEMBLY

(71) Applicant: ASB Systembau Horst Babinsky GmbH, Stein (DE)

(72) Inventor: Christof Babinsky, Rosenheim (DE)

(73) Assignee: ASB Systembau Horst Babinsky GmbH, Stein (DE)

(21) Appl. No.: 18/437,943

(22) Filed: Feb. 9, 2024

(51) Int. Cl. E04F 15/22; E04F 15/024; H01L 25/075; H01L 33/58

(52) U.S. Cl. CPC E04F 15/225; E04F 15/02405; E04F 15/02458; H01L 25/0753; H10H 20/855

(57) ABSTRACT

A floor assembly may include an elastic support structure, an array of display devices mounted on the elastic support structure, and a translucent surface panel covering the array and supported by the array.

### CROSS REFERENCE TO RELATED APPLICATIONS

This patent application is related to U.S. patent application Ser. No. 18/437,834, filed Feb. 9, 2024, titled “Floor Assembly,” which is incorporated herein by reference in its entirety.

### BACKGROUND

### Technical Field

The present disclosure relates to a floor assembly, in particular a floor assembly incorporating display devices, such as light emitting diode (LED) display devices. Particularly, the disclosure relates to a sports floor assembly in which LED display devices may illuminate and thereby illustrate field markings and/or other images in a dynamic manner.

### Technical Background

US 2004/0240230 A1 relates to a surface light-emitting device installed along a floor for lighting or decorative purposes. The device includes a light-emitting unit having a box-shaped casing with an open top, a plate-shaped reinforced plastic material installed in the top opening of the casing, a plate-shaped light-diffusing member below the reinforced plastic material, and a fluorescent tube or other light source for irradiating the light-diffusing member. The light source is arranged horizontally next to the light-diffusing member, in the outer circumferential box frame, facing inwards. Bolts for holding the devices are arranged at each corner thereof. Multiple devices can be arranged in vertical and horizontal rows. Each device is equipped with a power supply and dimming console arranged at the bottom. Each device can display an individual color so that a floor made from surface light-emitting devices forms a screen having a number of pixels corresponding to the number of devices, thereby limiting the image resolution of the screen substantially. The box-shaped casing surrounding each reinforced plastic plate causes interruptions in an image displayed by such a floor, which is detrimental to image quality and renders such a floor unable to display field markings. The box-shaped casing and bolt holes pose a risk for injuries and make the floor uneven so that the surface light-emitting devices may be used for decorative purposes but not as a playing field for sports.

US 2012/0042586 A1 describes a floor type multi-display apparatus comprising a plurality of displays, transparent panels and support members. The transparent panels are disposed in a coplanar manner to form a floor. They are spaced upwardly apart from the displays to define a gap therebetween. The plurality of transparent panels is supported by the support members. The support members include first support members disposed between adjacent displays in a scattered fashion, and second support members disposed around the multi-display. The support members are made of stainless steel and have respective plate portions positioned along and closely to edges of the displays. The support members carrying the transparent panels cause shadows and other interruptions affecting the image displayed by the display units. When the displays are used to show field markings, they will be visible in different places relative to the feet of the athletes and the balls they use depending on the individual viewing angle of the athlete, referee, spectator or camera, which renders the floor unsuitable for competitive or professional sports. Furthermore, heavy objects or athletes falling on critical spots of a transparent panel pose a risk of damage to the floor type-multi display apparatus and consequently a risk of injuries for the athletes. Athletes have also complained that the floor type multi-display apparatus occasionally causes a ball to behave in an irregular manner.

US 2012/0297713 A1 relates to an illuminated floor assembly. The floor assembly includes a composite glass floor panel suspended above an overlay and a substructure using polymer pads. The polymer pads are arranged along the edges of neighboring composite glass floor panels. Hook and loop fasteners attach the glass floor panels to the polymer pads below. An LED light channel is arranged between the composite glass floor panel and the overlay. Several LED light channels can be provided to illuminate field markings of a sports arena. The light channels can be designed to enable the representation of symbols or advertising. The illuminated floor assembly is known to provide excellent mechanical properties for athletes to compete thereon in different sports such as basketball, handball, squash and volleyball. However, only a small portion of the playing field can be used to display field markings or other symbols, and the markings or symbols which can be displayed are limited according to the structure of the light channels. If light channels are arranged in close proximity to one another, the image quality may be adversely affected by interruptions or shadows of the channel walls. Furthermore, the playing field to becomes stiff where channels are arranged close to each other.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 a schematic illustration of a floor assembly according to the disclosure.

FIG. 2 an exemplary illustration of an assembly unit for a floor assembly according to the disclosure.

FIG. 3 a schematic illustration of a composite glass floor panel according to the disclosure.

FIG. 4 a schematic illustration of a pair of adjacent composite glass floor panels according to the disclosure.

FIG. 5 a detailed side view of a floor assembly according to the disclosure.

FIG. 6 a detailed view of a glass floor panel on a display unit according to the disclosure.

FIG. 7 a sectional view of a display device box structure according to the disclosure.

FIG. 8 a partial perspective illustration of a sports floor assembly according to the disclosure.

FIG. 9 a perspective view of a rigid substructure and an elastic support structure of a floor assembly according to the disclosure.

FIG. 10 a perspective view of floor assembly including multiple assembly units according to the disclosure.

FIG. 11 a detailed side view of a pair of assembly units of a floor assembly according to the disclosure.

FIG. 12 a schematic perspective view of a composite glass floor panel according to the disclosure.

FIG. 13 a schematic perspective view of another composite glass floor panel according to the disclosure.

The exemplary embodiments of the present disclosure will be described with reference to the accompanying drawings. Elements, features and components that are identical, functionally identical and have the same effect are—insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

Hereinafter, various embodiments of the present disclosure will be described in detail with reference to the accompanying drawings so that those skilled in the art can easily carry them out. The present disclosure can be modified in various different ways, and is not limited to the embodiments set forth herein.

Further, in the drawings, the size and thickness of each element are arbitrarily illustrated for convenience of description, and the present disclosure is not necessarily limited to those illustrated in the drawings. In the drawings, the thickness of layers, regions, etc. are exaggerated for clarity. In the drawings, for convenience of description, the thicknesses of some layers and regions are exaggerated.

In addition, it will be understood that when an element such as a layer, film, region, or plate is referred to as being “on” or “above” another element, it can be directly on the other element or intervening elements may also be present. In contrast, when an element is referred to as being “directly on” another element, it means that other intervening elements are not present. Further, the word “on” or “above” means disposed on or below a reference portion, and does not necessarily mean being disposed on the upper end of the reference portion toward the opposite direction of gravity. Meanwhile, similarly to the case where it is described as being located “on” or “above” another part, the case where it is described as being located “below” or “under” another part will also be understood with reference to the above-mentioned contents.

Further, throughout the description, when referred to as “planar”, it means when a target portion is viewed from the upper side, and when referred to as “cross-sectional”, it means when a target portion is viewed from the side of a cross section cut vertically.

Throughout the description, when a portion is referred to as “including” or “comprising” a certain component, it means that the portion can further include other components, without excluding the other components, unless otherwise stated. Throughout the specification, unless stated otherwise, each element may be singular or plural.

Additionally, when an element is referred to as being “connected”, “coupled” or “linked” to another element, the element can be directly connected or coupled to the other element, but it should be understood that intervening elements may be present between each element, or each element may be “connected”, “coupled” or “linked” to each other through another element.

Throughout the specification, “A and/or B” refers to either A or B or both A and B unless expressly stated otherwise, and “C to D” refers to C or greater and D or smaller unless expressly stated otherwise.

Hereinafter, a system and a method for extracting active material residue as well as a method of coating an electrode with an active material layer for manufacturing a battery and a corresponding assembly are described with reference to the accompanying drawings.

The skilled person understands that any optical parameters referred to herein such as “transparent”, “translucent”, etc., refer to properties or light in the spectrum visible to the human eye, in particular to light having a wavelength of 380 to 700 nanometers, except if expressly indicated otherwise. Spectrophotometric values may in particular be determined according to EN410-2011. The term “translucent” may generally be understood in that a translucent object allows the passage of light but not a clear view of what lies beyond.

It is an objective of the present disclosure to overcome the disadvantages of the conventional techniques, in particular to provide a floor assembly configured to act as a display but nevertheless having excellent mechanical and sports-physical properties, in particular to provide a safe and stable ground for athletes to compete on. It is desired that the floor assembly is easy to handle, in particular for assembly, disassembly, maintenance and/or repair.

Accordingly, the present disclosure relates to a floor assembly comprising an elastic support structure, an array of display devices mounted on the elastic support structure, and a translucent surface panel covering the array and supported by the array. The floor assembly according to the present disclosure may be a sports floor assembly. A sports floor assembly is configured for athletes to perform their respective sport thereon (e.g. badminton, basketball, handball, field hockey, soccer, squash, tennis, volleyball). The sports floor assembly may be configured to form part or all of a playing field in a sports arena.

The elastic support structure is configured to resiliently mount the translucent surface panel on top of the array of display devices. The elastic support structure provides elasticity in the vertical direction to the floor assembly. In the vertical direction, the elastic support structure may be as elastic as or more elastic than the translucent surface panel. The elastic support structure is more elastic in the vertical direction than the array of display devices. In particular, the elastic support structure is arranged below predefined sections of the array and/or of the translucent floor panel. The display devices may in particular be mounted on the elastic support structure such that an elastic displacement of the translucent surface panel supported by the array causes a corresponding elastic deformation of the elastic support structure. The elasticity of the elastic support mount in the vertical direction may be at least as large as or larger than, in particular substantially larger than, the elasticity of the array of display devices. The elasticity of the elastic support mount in the vertical direction may be at least as large as or larger than, in particular substantially larger than, the elasticity of the translucent surface panel. The elastic support structure is configured to provide for all or at least the majority of a local vertical deformation of the floor assembly. A vertical deformation, in particular constriction, of the floor assembly in comparison to a resting state thereof may cause a corresponding vertical deformation of the elastic support structure, wherein the vertical deformation of the support structure is at least 50% of the total vertical deformation experienced locally by the floor assembly, in particular at least 75% or at least 90% thereof. The first horizontal direction may be perpendicular with respect to the second horizontal direction. The first and second horizontal directions may be perpendicular to the vertical direction. The vertical direction may be defined corresponding to the direction of gravity.

The surface panel is configured to act as a floor surface for athletes to move directly thereon. In particular, the surface panel is configured for athletes to perform their respective sport thereon (e.g. badminton, basketball, handball, field hockey, soccer, squash, tennis, volleyball). The surface panel is at least sectionally translucent for light in the visible range. For example, the surface panel may be at least partially intransparent (e.g, at least partially opaque), or completely intransparent. A material will appear completely transparent if it has no properties that compete with light transmission through the material, either by (partially or completely) absorbing the light or by scattering the light in different directions. In some embodiments, most of the surface panel (e.g. at least 90%, at least 95% or at least 99% referring to the vertically oriented surface area of the surface panel) or the entire surface panel may be translucent for light in the visible spectrum. The translucent surface panel may have a rectangular shape. The translucent surface panel may have a substantially flat body shape. The panel thickness of the translucent surface panel in the vertical direction may be constant. The panel thickness may be in the range of 5 mm to 30 mm, in particular 8 mm to 20 mm. The translucent surface panel has a first width (panel length) extending in a first horizontal direction and a second width (panel width) extending in a second horizontal direction. The panel length and the panel width may be in the range of 50 cm to 500 cm. The panel length may be at least as large as the panel width. In particular, the panel length is larger than the panel width. The panel length may in some embodiments be 1 to 2 times as large as the panel width, in particular 1,2 times to 1.5 times as large. An exemplary panel length may be 1.6 m to 3 m, in particular 1.8 m to 2.5 m, more particularly 2 m. An exemplary panel width may be 1 m to 2 m, in particular 1.2 m to 1.7 m, more particularly 1.5 m. The first and second width of a panel may be substantially larger than the panel thickness. The second width may be at least 50 times as large as the panel thickness, in particular at least 100 times as large as the second width. The second width may be no more than 300 times as large as the panel thickness, in particular at least 200 times as large as the first width.

In particular, the display devices face in an upward direction. The array of display devices may for example comprise an LED display screen. The LED display device may comprise a flat panel display. The array may be composed of a plurality of LED display devices arranged in sequence. The array may comprise a plurality of display devices (cabinets) connected by splicing in a first (lengthwise) horizontal direction and splicing in a second (crosswise) horizontal direction to realize an array of display devices. The array may realize a large-screen display. By providing the floor assembly with the array, the sports arena may realize one large-screen displays or include one or more large-screen displays. In some embodiments, the array of display devices, in particular the mechanical structure of the array of display devices, more particularly the display devices including a flat panel display supported by a box structure, may be configured based on CN 108 682 320 A or CN 219 536 489 U. CN 108 682 320 A and CN 219 536 489 U are hereby incorporated by reference with the provision that, in accordance with the present disclosure, the LED display devices are arranged in a substantially horizontal plane rather than a plane extending horizontally and vertically. The plurality of LED display devices of the array may be directed at the translucent surface panel. The array may comprise a first number of display devices arranged sequentially in a first (lengthwise) horizontal direction, such as three, four or five display devices, all of which are covered by the same translucent surface panel. The array may comprise a second number of display devices arranged sequentially in a second (crosswise) horizontal direction, such as two or three display devices, all of which are covered by the same translucent surface panel. In an exemplary embodiment, all of the display devices of a floor assembly or an assembly unit of a floor assembly may be covered by the same translucent surface panel. The first number of display devices may be equal to or larger than the second number of display devices in the array. All of the display devices may have the same shape. Each display device may in particular have a rectangular (e.g., square) surface shape. The display devices may have a side length in the first horizontal direction and/or in the second horizontal direction between 10 cm and 100 cm, in particular between 20 cm and 60 cm, for example 25 cm or 50 cm. A display device may have a square shape having a width and length of, for example, 50 cm. The display device may for example have grid comprising rows and columns of LEDs. The display device may for example include a grid having no less than 10×10 LEDs (number of LEDs in one column×number of LEDs in one row), no less than 50×50 LEDs, no less than 100×100 LEDs or no less than 150×150 LEDs. If there are too few LEDs in each LED device, the image quality may be of subpar quality. The number of LEDs in a grid of one display device may be less than 1000×1000, in particular less than 400×400, more particularly less than 200×200. If there are too many LEDs per LED device, the power consumption may become excessive or the framerate may suffer. A display device may comprise multiple rows and columns of LEDs. A display device may be configured to have 1 to 10 LEDs per cm, in particular 2 to 5 LEDs per cm, more particularly 3 to 4 cm, in each row (LED pitch). Additionally, or alternatively, the device may be configured to have 1 to 10 LEDs per cm, in particular 2 to 5 LEDs per cm, more particularly 3 to 4 cm, in each column. In an exemplary embodiment, the LED pitch of the LED rows and LED columns in an LED device are equal. In particular, the first panel width may be a whole multiple of the first side length of the display devices covered by the panel. The second panel width may in particular be a whole multiple of the second side length of the display devices covered by the panel. In an exemplary embodiment, the translucent surface panel may be dimensioned so as to cover the array of display devices in a substantially flush manner in the vertical direction.

The translucent surface panel covering the array may provide a rear projection surface for an image projected by the display devices, in particular the LED display screen. By providing a surface panel which is translucent above the display devices, the image of field lines or other symbols emitted by the display devices appears on the surface of the floor assembly. Thereby, it appears as if the athletes stepping on the surface panel and the balls with which they play come into immediate contact with the projected image of field markings on the top surface of the floor assembly, regardless of the individual viewpoint of the athlete, referee, spectator or camera. By directing the display device at the translucent surface panel, confusion regarding the question whether an athlete or ball was on one side of a projected field marking or on the other side can be avoided. The translucent surface panel is supported by the array such that the mechanical forces acting on the panel from people standing, walking, running or jumping on the panel, balls rolling or bouncing on the panel or generally objects or people resting or moving on the floor assembly are transferred from the translucent floor panel onto the array of display devices. The display devices bear the weight of the display devices and that of objects or people on top of the panel. Additionally, the array of display devices bears the impact of any vibrations, forces or impulses, etc., acting on the panel. In particular, the translucent surface panel may be supported by at least half of the display devices, or at least 75% or all of the display devices of the array covered by the panel. The array of display devices may support the translucent surface panel such that the panel and the array move and/or deform together in case of an elastic displacement of the translucent surface panel in the vertical direction. Additional support members between the translucent surface panel and the elastic support structure can be avoided. By arranging the translucent surface panel to be supported by the display devices, vertical gaps between the display devices and the panel, or support pillars standing on the elastic support structure provided for supporting the translucent surface panel can be avoided, thereby improving the stability and homogeneity of the floor assembly and minimizing the risk of damages or injuries.

In some embodiments, the array is interposed between the translucent surface panel and the elastic support structure. The array may bridge the vertical distance between the elastic support structure and the translucent surface panel. In particular, substantially all of the vertical distance between the elastic support structure and the translucent surface panel may be occupied by the array of display devices. It shall be clear that the array of display devices may contain hollow spaces, such as gaps between members of a framework structure or hollow spaces surrounded, in particular encased, by the display devices. The floor assembly according to the present disclosure may be realized as a layered structure in which the array of display devices forms an interlayer between the translucent surface panel which forming an upper layer and the elastic support structure forming a lower layer. Optionally, a rigid substructure may additionally be provided below the elastic support structure forming a substructure layer, and in this case the elastic support structure may realize an interlayer between the layer formed by the array of display devices and the substructure layer. Any forces acting onto the translucent surface panel may be transferred to the elastic support structure through the array of display devices. Contrary to the prejudice according to which display devices should supposedly be relieved of any stress acting on a surface panel above the display devices due to external loads, it was determined that a particularly advantageous mechanical structure can be formed when external loads are transferred from the translucent surface panel on which the external load acts through the display devices into the underlying elastic support structure. The floor assembly is stable and resilient and shows a homogeneous mechanical behavior which reliably allows athletes to perform thereon.

In particular, the translucent surface panel rests directly on the array of display devices. For example, the translucent surface panel may rest directly on an LED display device. An LED display device may comprise a flat panel display including protrusions, such as pillars, dam-like protrusions or wall-like protrusions, interposed between an array of light emitting diodes (LEDs). The LEDs may be arranged in grooves or similar retractions, below the tip of the protrusions of the LED display device. The translucent surface panel may rest directly on top of a plurality of protrusions of the LED display device.

In some embodiments of the floor assembly, the display devices include a respective box structure. In particular, each display device of the array may be provided with a respective box structure. The box structure may be configured to horizontally surround a display unit. The display unit may, alternatively or additionally, be suspended by the box structure (or short: box). The display unit of the display device includes the light emitting members (e.g., LEDs) of the display device, and the electronics for powering and/or controlling these light emitting members. The box or box structure may comprise a rigid frame comprising first beams extending in the first direction and second beams extending in the second direction. The first and second beams may form a rectangular, in particular square, frame. The beams may be made of a metal material, such as a steel alloy or an aluminum alloy. The first beams and the second beams may be rigidly attached to one another, for example by welding, to form the box structure. The box structure extends in the vertical direction and may span all or at least 50%, in particular at least 75% or at least 90% of the vertical height of the array. The flat panel display may or may not protrude above the box in the vertical direction. The box structure may be configured in accordance with the box or box body described in CN 108682320 A or CN219536489U.

Another aspect of the present disclosure relates to a floor assembly which comprises an elastic support structure, an array of interlocked box structures mounted on the elastic support structure and a translucent surface panel covering the array and supported by the array. The assembly may comprise a layered structure including the translucent surface panel on top of the array of box structures which may or may not contain display units. In the layered assembly, the box structures may be interlocked in a first and/or second horizontal direction. Interlocked devices may form a large surface area of practically uniform mechanical parameters, in particular elastic parameters. Adjacent interlocked box structures are mechanically connected in a first and/or second horizontal direction. By interlocking adjacent box structures along an edge thereof, they may be adapted to act as one. Interlocking adjacent box structures may in particular rigidly attach the interlocked pair of box structures to each other such that stress and strain is transferred from one box structure to the next along their mutual edge in at least one of the vertical direction, the first horizontal direction and/or the second horizontal direction perpendicular to the first horizontal direction. By interlocking, a chain-like connection of the box structures may be realized. The assembly may include an interlocked array as a bed for the floor panel arranged thereon. By providing the floor assembly with an array of interlocked box structures, the floor assembly may have evenly distributed homogeneous mechanical, in particular elastic, properties. The first and second aspects of the present disclosure may be combined with one another.

In a further development of a floor assembly with an assembly of display devices including box structures, the array may be spliced together using connecting members configured to releasably connect box structures of adjacent box structures. In particular, the array may comprise display devices spliced together using connecting members configured to releasably connect box structures of adjacent display devices. The connection members may include connection configured to provide a releasable attachment of adjacent box structures. The box structures may include receptions for receiving and possibly arresting connection members. The connection members may be configured to transfer forces acting in the vertical direction from a first box structure to a second box structure coupled to the first box structure. Additionally, the connection members may be configured to transfer forces acting in a first and/or second horizontal direction from a first box structure to a second box structure coupled to the first box structure.

In another further development of a floor assembly with an array of display devices including box structures, which may be combined with the above-mentioned one, the elastic support structure comprises a plurality of support pads arranged below the display devices to carry the box structures. The box structures may have one or more foots protruding downward from the respective box structure, in particular four foots arranged in the corners of the respective box structure, and each support pad may be arranged below a respective foot. In an exemplary embodiment, each first support pad may be associated with several box structures.

A first group of support pads my arranged along the circumference of the floor assembly below the edges of two adjacent box structures and/or below the edges of two adjacent display devices. Support pads of the first group arranged in the corners of an assembly unit may be associated with only one respective foot. Support pads of the first group arranged along the edge of an assembly unit may be associated with two foots of two adjacent display devices. In an exemplary embodiment, the first and/or first group of support pads are part of (only) one assembly unit which may be defined by one respective translucent surface panel or one respective rigid substructure. In an exemplary embodiment, the first group of support pads does not extend beyond the circumference of the translucent surface panel, neither in the first horizontal direction nor in the first horizontal direction.

Additionally, a second group of support pads may be arranged below the corners of four adjacent box structures and/or below the corners of four adjacent display devices. The second group of support pads may in particular be arranged inward of the lateral edges forming the circumference of the translucent surface panel in the second and/or second horizontal direction. In particular, the same support foot of the second group may be associated with the four foots of four adjoining corners of mutually adjacent display units. In particular, each support pad may be arranged at at least one of the edges and the corner of a box structure.

In a further development of a of a floor assembly comprising support pads includes first support pads. The first support pads may be elastic. An elastic first support pad may be configured to have a tensile strength in the range of 0.25 N/mm² to 0.75 N/mm², in particular 0.4 n/mm² to 0.6 N/mm², more particularly 0.5 N/mm² (in particular according to DIN EN ISO 1798 (“Flexible cellular polymeric materials—Determination of tensile strength and elongation at break (ISO 1798:2008)”, Deutsches Institut für Normung e.V. (DIN), April 2008). An elastic first support pad may be configured to have a compressive strength in the range of 0.25 N/mm² to 0.75 N/mm² at 25% deformation, in particular 0.4 n/mm² to 0.6 N/mm² at 25% deformation, more particularly 0.55 N/mm² at 25% deformation (in particular according to DIN EN ISO 3386-2:2010-09 (“Flexible cellular polymeric materials-Determination of stress-strain characteristics in compression—Part 2: High-density materials (ISO 3386-2:1997+Amd 1:2010)”, Deutsches Institut für Normung e.V. (DIN), September 2010) The first pads may be made of, in particular consist of, an elastic polymer material, such as Regupol® and/or PUR-bonded rubber granules. The first group of support pads may consist of a plurality of first pads. The first pads may be mounted, in particular directly, on a rigid substructure. In particular, the first pads may be arranged vertically aligned above pillars of a rigid substructure. The first pads may have a thickness in the range of 1 mm to 30 mm, in particular 3 mm to 20 mm, for example 6 mm, 8 mm, or 10 mm.

A further development of a of a floor assembly comprising support pads may alternatively or additional, the elastic support structure includes second support pads. The second pads may be rigid. A rigid second support pad may have a tensile strength may be configured to have a tensile strength in the range of 1.5 N/mm² to 5 N/mm², in particular 1.75 n/mm² to 2.5 N/mm², more particularly 1.9 N/mm² (in particular according to DIN EN ISO 1798 (“Flexible cellular polymeric materials-Determination of tensile strength and elongation at break (ISO 1798:2008)”, Deutsches Institut für Normung e.V. (DIN), April 2008). An rigid second support pad may be configured to have a compressive strength in the range of 1.5 N/mm² to 5 N/mm² at 25% deformation, in particular 1.75 n/mm² to 2.5 N/mm² at 25% deformation, more particularly 1.9 N/mm² at 25% deformation (in particular according to DIN EN ISO 3386-2:2010-09 (flexible cellular polymeric materials+Determination of stress-strain characteristics in compression—Part 2: High-density materials (ISO 3386-2:1997+Amd 1:2010)”, Deutsches Institut für Normung e.V. (DIN), September 2010). The second pads may be made of, in particular consist of, a rigid polymer material, such as polyurethane (PU). The second group of support pads may consist of a plurality of second pads. The second pads may be indirectly mounted on a rigid substructure. In particular, the second pads may be arranged distanced with respect to all pillars of the rigid substructure in a first and/or second horizontal direction. The second pads may have a thickness in the range of 1 mm to 30 mm, in particular 3 mm to 20 mm, for example 6 mm, 8 mm, or 10 mm. The thickness of the first and second pads may be equal.

The elastic support structure may comprise a plurality of beam-like spring members, such as flat springs or leaf springs. The beam-like spring members may in particular be fixed to the rigid substructure and interposed between the second pads and the rigid substructure to carry the second pads. The plurality of beam-like spring members in particular comprises a first set of spring members extending in a first (lengthwise) horizontal direction and a second set of spring members extending in a second (crosswise) horizontal direction. The plurality of beam-like spring members may in particular form a mesh of interconnected beam-like spring members. First beam-like spring members may be firmly attached, for example using bolts or rivets, to second beam-like spring members to form the mesh. The second support pads may be arranged on the mesh. The second support pads may in some embodiments be attached on the first set of spring members and be distanced from the second set of spring members in the first direction. Alternatively, the second support pads may be attached on the second set of spring members and be distanced from the first set of spring members in the second direction.

In some embodiments of the floor assembly, which may be combined with the abovementioned embodiments, the floor assembly further comprises a rigid substructure on which the elastic support structure is suspended. The rigid substructure may be made of a metal material, such as a steel alloy or an aluminum alloy. In an exemplary embodiment, the rigid substructure may include a cast aluminum body. A leg of the rigid substructure may protrude below the floor assembly. In particular, the floor assembly or assembly unit may be configured to be positioned on a floor using the plurality of legs, in particular exclusively the plurality of legs. The rigid substructure may be provided with a plurality of legs, in particular three or four legs. The plurality of legs may be arranged in the corners of the floor assembly. The plurality of legs may be disposed inward of the circumference of the floor assembly or assembly unit, in particular inward of the circumference of the translucent surface panel. One or more of the plurality of legs may be height adjustable to allow for unevenness of the ground below the floor assembly. An adjustment interface for controlling the height of one or more, in particular all, of the plurality of legs, may be arranged on a single lateral side, in particular a first lengthwise side edge or a first crosswise side edge, of the floor assembly or assembly unit.

Further developments of a floor assembly comprising a rigid substructure may include a plurality of pillars. The elastic support structure may rest, in particular exclusively, on the pillars. First pads may be mounted directly above pillars. Second pads may be connected to pillars and be offset from the pillars in the first and/or second horizontal direction. Beam-like spring members may be mounted directly on the pillars. The pillars may protrude from the rigid substructure, in particular a cast aluminum body thereof, in the vertical direction. In an exemplary embodiment, the spaces between adjacent pillars may be hollow so as to allow for a vertical displacement of the elastic support structure into the spaces. For example, spaces may be provided between adjacent pillars to allow beam-like spring members suspended on the adjacent pillars to be vertically displaced into these spaces.

In some embodiments of the floor assembly which may be combined with the ones described above, the translucent surface panel comprises or consists of a composite glass panel comprising a cover layer made of a first glass panel, a base layer made of a second glass panel, and an intermediate layer made of at least one polymer film. The cover layer, the intermediate layer and the base layer are sequentially laminated. In some embodiments of the floor assembly, a light diffusion layer is formed in the cover layer of the floor panel, The light diffusion layer may in particular be formed at a surface of the cover layer. The cover layer may be processed to have at least one roughened surface. The light diffusion layer may be created through erosion of a surface of the cover layer, for example through mechanical erosion, e.g. by scratching, scraping, brushing, grinding, sanding, abrasion, or the like. Alternatively, or additionally, the light diffusion layer may be created through chemical erosion of the cover layer. In an exemplary embodiment, the light diffusion layer may be formed at the top surface of the cover layer. Light diffusion may be understood to refer to light scattering and/or spreading out in various directions as it interacts with the light diffusion layer. Light diffusion in the light diffusion layer may cause light to disperse in different directions, in particular due to interactions with microscopic irregularities or variations in the light diffusion layer. Light diffusion in the light diffusion layer in particular differs from a direct transmission through a transparent medium, in particular a transparent base layer or a transparent intermediate layer, where light travels in a substantially straight line. The light diffusion layer exhibits light diffusion. The light diffusion layer may in particular lack clarity and/or lack transparency. The light diffusion layer is in particular configured to scatter light (light scattering layer).

The first glass panel may in particular be made of security glass according to EN 12150 (DIN EN 12150-1, “Glass in building—Thermally toughened soda lime silicate safety glass—Part 1: Definition and description”, Deutsches Institut für Normung e.V. (DIN), July 2020; DIN EN 12150-2:2005, “Glass in building—Thermally toughened soda lime silicate safety glass”, Deutsches Institut für Normung e.V. (DIN), January 2005), in particular SGG securit®. The second glass panel may in particular be made of security glass according to EN 12150 (see above), in particular SGG securit®. The composite glass floor panel may comprise one or more additional layers between the cover layer and the base layer. Optionally, the composite glass floor panel may comprise one or more additional layers arranged below the base layer. In an exemplary embodiment, the intermediate layer may be bonded between two layers of glass. The intermediate layer may be bonded directly to the cover layer. The intermediate layer may be bonded directly to the base layer. The intermediate layer may be arranged, in particular directly, on the bottom of the cover layer. The base layer may be arranged, in particular directly, on the bottom of the intermediate layer. Such a three-layered composite glass floor panel may be able to provide the floor assembly with a particularly advantageous combination of mechanical and optical properties.

In some embodiments, the at least one polymer film of the intermediate layer comprises or consists of at least one of polyvinyl butyral (PVB), ethylene-vinyl acetate (EVA), ionoplast polymers, cast in place (CIP) liquid resin, and thermoplastic polyurethane (TPU). In particular, the at least one polymer film further comprises a colorant. The polymer film may be provided with at least one colorant to set the light transmission rate of the intermediate layer, in particular of the composite glass floor panel. The skilled person understands that the polymer film may comprise additional additives.

In some embodiments of the floor assembly according to the present disclosure, the thickness of the composite glass floor panel may be in the range of 8 mm to 15 mm, in particular in the range between 10 mm and 13 mm, preferably in the range 11 mm to 12 mm. Larger glass floor panels tend to be increasingly heavy and stiff. Thinner glass floor panels are increasingly susceptible to mechanical damage. The thickness of the cover layer may be in the range of 4 mm to 6 mm, in particular in the range between 4.5 mm and 5.5 mm, preferably 5 mm. The thickness of the intermediate layer may be in the range of 0.5 mm to 3.0 mm, in particular in the range between 1.0 mm and 2.0 mm, preferably 1.4 mm to 1.6 mm. The thickness of the base layer may be in the range of 4 mm to 6 mm, in particular in the range between 4.5 mm and 5.5 mm, preferably 5 mm. In an exemplary embodiment, the thickness of the cover layer may be substantially equal to the thickness of the base layer. The thickness of the intermediate layer may be smaller than the thickness of the cover layer and/or smaller than the thickness of the base layer. In particular, the thickness of the intermediate layer may be smaller than one half of the thickness of the cover layer and/or smaller than one half of the thickness of the base layer.

In some embodiments of the floor assembly, the cover layer is provided, in particular on its top surface, with a pattern, in particular a regular pattern, of glass dots or ceramic dots. Dots may in particular comprise or consist of a translucent material. Optionally, dots may comprise or consist of a reflective material, in particular comprise reflective microparticles, such as silver microparticles. The dots may in some embodiments have a circular shape. The dots are distanced from each other and the dots define an average dot diameter. The distance between adjacent dots may be substantially larger than the average dot diameter. In some embodiments, the distance between adjacent dots may be smaller than the average dot diameter. The distance between adjacent dots (e.g. in a row of dots or in a column of dots) may be determined as the distance between the center of two immediately adjacent dots (dot pitch).

The distance between adjacent dots (dot pitch) may be configured to be in the range between 2 mm and 15 mm, in particular in the range between 3 mm and 10 mm, more particularly in the range between 5 mm and 8 mm. In an exemplary embodiment, the distance between adjacent dots may be no more than 10 mm, in particular no more than 8 mm or no more than 7 mm. In some embodiments, the distance between adjacent dots may be between 6 mm and 7 mm, in particular 6.4 mm.

The average dot diameter may be in the range of 0.1 mm to 15 mm, in particular in the range of 0.5 mm to 11 mm. In some embodiments, for example in case the floor assembly is configured to be used as a basketball playing field, the average dot diameter may be in the range of 0.4 mm to 1.5 mm, in particularly 0.6 mm to 1 mm, more particularly 0.8 mm. The average diameter may for example be 0.8 mm or 1 mm. In some embodiments, for example in case the floor assembly is configured to be used as a squash playing field, the average dot diameter may be in the range of 2 mm to 10 mm, in particularly 2.5 mm to 5 mm. The average diameter may for example be 2.5 mm, 3 mm, 3.5 mm or 5 mm. In some embodiments, such as outdoor playing fields, the average dot diameter may be in the range of 5 mm to 15 mm, in particularly 8 mm to 12 mm, more particularly 8 mm to 10 mm. For some playing fields (e.g. a squash field) it may be desired to have a first region (e.g. playing region) with a medium grip using medium sized dots, for example of 2.5 mm diameter, and a second region (e.g. a border region) having a strong grip using larger dot diameters, of for example 5 mm. Dots of such a size and spread on the one hand improve grip for athletes to move safely while not affecting the optical quality of the sports floor assembly. However, depending on the application, it may be desired not to increase the grip above a certain threshold.

In an exemplary embodiment, the dots in a row or column may have a constant average diameter and/or constant pitch. In particular, the glass floor panel may be provided exclusively with dots of constant shape and size, in particular of the same average diameter. Alternatively, or additionally, the glass floor panel may be provided exclusively with regularly spaced dots, in particular dots arranged in columns of a constant dot pitch and/or row of a constant dot pitch.

In particular, one translucent surface panel, particularly one glass floor panel, is associated with one respective rigid substructure of a floor assembly. The translucent surface panel may in particular be aligned flush with the rigid substructure in the vertical direction. Furthermore, translucent surface panel may be aligned flush with the array of display devices in the vertical direction. Additionally, or alternatively, the array of display devices may be aligned flush with the rigid substructure in the vertical direction. The floor assembly or assembly unit (including empty spaces inside of the assembly or unit) may have a generally cubic shape. Several cubic floor assembly units may be arranged

The floor assembly may in particular comprises a plurality of assembly units. In an exemplary embodiment, the assembly units of the floor assembly may be uniform, i.e. of the same design and size, or at least substantially of the same design and size. Each assembly unit comprises a respective elastic support structure, a respective array of display devices mounted on the elastic support structure, and a respective translucent surface panel. The assembly units of the floor assembly are arranged in rows and columns. The translucent surface panels of the plurality of assembly units are configured to be arranged to form a smooth surface. In particular, the surface panels of the plurality of assembly units are arranged flush in the first horizontal direction and in the second horizontal direction so as to form a level playing field. In an exemplary embodiment, the floor assembly may include a plurality of arrays covered by a corresponding plurality of translucent surface panels. Each assembly unit may be handled, in particular transported, stored and/or set up, individually. For example, each assembly unit may be transported individually as a complete unit using a conventional forklift. Several assembly units may be stacked on top of each other for storage or transportation in a freight container (e.g. on a truck or ship). Dividing the floor assembly into multiple individual assembly units allows for a rapid assembly and disassembly which is important for using the floor assembly in an event location. Furthermore, a floor assembly consisting of multiple assembly units allows to quickly replace faulty components without long impairments to the playing field. The use of uniform assembly units allows to create a playing field which is safe to use for athletes and displays homogeneous behavior.

In some embodiments of the floor assembly comprising a plurality of assembly units, each assembly unit further comprises a respective rigid substructure. In each assembly unit, one respective translucent surface panel, in particular one respective glass floor panel, is associated with the respective rigid substructure. Each assembly unit may comprise a respective array of display devices covered by the respective translucent surface panel of the assembly unit. The array of display devices of an assembly unit is sandwiched between the translucent surface panel and the rigid substructure.

The plurality of assembly units of a floor assembly may be arranged to form pairs of adjacent translucent surface panels. A gap may be defined between each pair of adjacent translucent surface panels. The gap may be linear. The gap has a gap length corresponding to the length of the pair of adjacent panels. A gap width is defined by the distance between the pair of adjacent panels. The gap width may be constant along the gap length. The gap may in particular be filled with a sealing member. The sealing member may comprise a sealing cord or the like. Additionally, or alternatively, the sealing member may comprise an elastic adhesive, such as a silicone adhesive, in particular a silicone adhesive made from a two-component mixture inside of the gap. The adhesive may be arranged in the gap above the sealing cord. The sealing member, in particular the sealing cord and/or, in particular and, the elastic adhesive, may be optically clear. In some embodiments of the floor assembly, the elastic adhesive of the sealing member may comprise or consist of Novasil S-SP 6764 (components mixed at the appropriate ratio) by Hermann Otto, Fridolfing. The optically clear sealing member may in particular be configured to have a light transmission rate the same as or larger than at least one or more, in particular all, of the translucent surface panels adjacent to the gap in which the sealing member is situated. The optically clear sealing member may have the same or substantially the same translucency properties as the adjacent composite glass floor panels. The light transmission of the optically clear sealing member may be no less than 0. times as large as, is in particular no less than 0.9 times, more particularly no less than 0.95 times the light transmission of at least one or both of the adjacent composite glass floor panels. If the sealing member transmits substantially less light than the adjacent panels, the image generated by the array of display devices becomes visibly interrupted. Alternatively, or additionally, the light transmission of the optically clear sealing member may be no more than 1.05 times as large as, is in particular no more than 1.1 times as large as, more particularly no more than 1.25 times as large as the light transmission of at least one or both of the adjacent translucent surface panels. If the sealing member is substantially more transparent than the adjacent panels, light from the light sources below would visibly leak through the gaps which would disturb an image generated by the floor assembly and possibly disturb athletes, referees or spectators. The optically clear sealing member may have a light transmission rate in the range of 60% to 99%, in particular at least 80% or at least 90%. The light transmission rate of the sealing member may in particular be in the range 75% to 97%, preferably in the range of 90% to 95%. By selecting an optically clear sealing member of similar transparency and light transmission in comparison to the adjacent translucent surface panels, the sealing member becomes virtually invisible for spectators watching an event on the floor assembly while the display devices are used to create an image. The optically clear sealing member may have the same or a higher transparency than the adjacent composite glass floor panels. Thus, the use of an optically clear sealing member allows the floor assembly to have a very good image quality.

In an exemplary embodiment of a floor assembly comprising a plurality of assembly units, the assembly units are attached to each other. The plurality of assembly units may be firmly coupled to one another. In particular, the arrays of display devices of adjacent assembly units may be spliced together using connecting members. The connecting members may be configured to releasably connect adjacent assembly units, in particular assembly units directly adjacent to each other in the first horizontal direction, or assembly units directly adjacent to each other in the second horizontal direction. The connecting members may be provided to splice display devices of adjacent assembly units together. In particular, the connecting members may be configured to splice box structures of adjacent assembly units together. A first group of connecting members may be provided inside of each assembly unit for splicing the box structures of the respective assembly of display devices of a respective assembly unit together. The first group of connecting members may be configured in accordance with a fixing mechanism or latching pin of CN 108682320 A or in accordance with a lock rod of CN219536489U.

In some embodiments of the floor assembly, the translucent surface panel is configured to have a light reflection rate in the range of 0.03 to 0.10, in particular in the range of 0.04 to 0.08, preferably in the range of 0.05 to 0.07. The light transmission rate may in particular be measured at an impact angle of 8° (in particular in accordance to the method defined in EN 410-2011; see above). Alternatively, the light transmission rate may be measured at an inclination of 85° (in particular in accordance to the method defined in EN 13745-2006 (DIN EN 13745, “Surfaces for sports areas—Determination of specular reflectance”, Deutsches Institut für Normung e.V. (DIN), May 2004)). It was found that floor assemblies having a reflection angle in the above-mentioned range cause less irritation to athletes and spectators. The floor assembly and a particularly low light reflection rate so that the field markings and the like created by the display devices can be perceived easily.

In some embodiments of the floor assembly, the translucent surface panel is configured to have a mirror gloss of less than 15%, in particular less than 10%, preferably in the range of 3% to 7%, more preferably in the range 4% to 6%. The mirror gloss may in particular be approximately 5%. The mirror gloss may be measured at an inclination of 85° (in particular in accordance to the method defined in EN 2813-2015 (DIN EN ISO 2813, “Paints and varnishes—Determination of gloss value at 20°, 60° and 85° (ISO 2813:2014)”, Deutsches Institut für Normung e.V. (DIN), February 2015)). The floor assembly has a particularly low mirror gloss so that the field markings and the like created by the display devices can be perceived easily and so that athletes and referees are not irritated by gloss.

In some embodiments of the floor assembly, the translucent surface panel, in particular the top surface thereof, is configured to have a slip resistance value (linear friction coefficient) in the range of 85 to 105, in particular in the range of 85 to 100, preferably in the range of 88 to 98. The friction coefficient may in particular be 89 or 95. The friction coefficient may be determined using a CEN rubber under dry conditions at a temperature of 23±2° C. (in particular in accordance to the method defined in EN 13036-4:2011 (DIN EN 13036-4, “Road and airfield surface characteristics Test methods Part 4: Method for measurement of slip/skid resistance of a surface: The pendulum test”, Deutsches Institut für Normung e. V.; Deutsches Institut für Normung e. V. (DIN), December 2011)).

In some embodiments of the floor assembly, the translucent surface panel is configured to have a ball rebound value of at least 90%, in particular at least 93%, preferably at least 95%. The ball rebound value may be determined by releasing a basketball from 1.8 m above the floor assembly, in comparison to a reference rebound value of said basketball on concrete (in particular in accordance to the method defined in EN 12235:2013 (DIN EN 12235, “Surfaces for sports areas—Determination of vertical ball behaviour”, Deutsches Institut für Normung e. V.; Deutsches Institut für Normung e. V. (DIN), December 2013).

In some embodiments of the floor assembly is configured to have an area-elastic vertical deformation value in the range of 1 mm to 4 mm, in particular in the range of 1.5 mm to 3.5 mm. The area-elastic vertical deformation value may be 2 mm or 3.2 mm. The deformation may be determined in millimeters under a standard load of 1500 N, in particular according to EN 14809 (DIN EN 14809; “Surfaces for sports areas-Determination of vertical deformation—Corrigendum 1”, Deutsches Institut für Normung e. V.; Deutsches Institut für Normung e. V. (DIN), April 2008).

In some embodiments of the floor assembly is configured to have an area-elastic force reduction value in the range of 40% to 60%, in particular in the range 45% to 55%. The force reduction value may in particular be 50%. The force reduction value may be determined in accordance with EN 14808 (DIN EN 14904:2006; DIN EN 14808, “Surfaces for sports areas—Determination of shock absorption”, Deutsches Institut für Normung e. V.; Deutsches Institut für Normung e. V. (DIN), March 2006; DIN EN 14904:2006, “Sportböden—Mehrzweck-Sporthallenböden”, Deutsches Institut für Normung e. V. (DIN), June 2006).

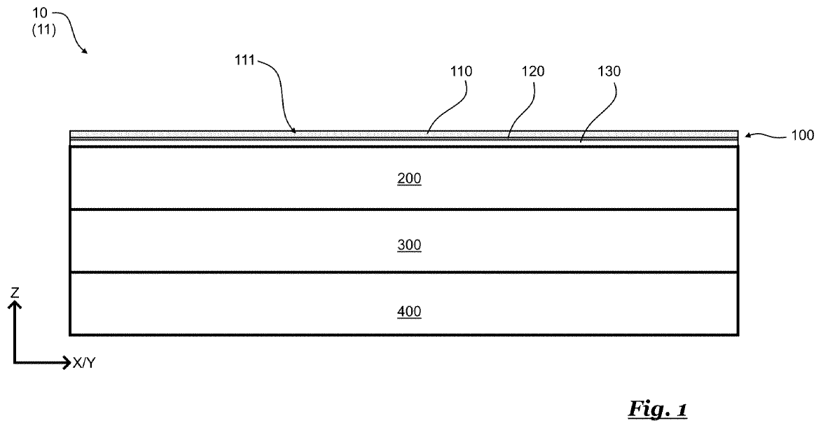

FIG. 1 shows a schematic illustration of a floor assembly 10. For ease of intelligibility, the floor assembly will generally be referred to as a sports floor assembly. However, it shall be clear that the floor assembly can be applied outside of sports applications, for example as an interactive floor assembly for a stage or the like. In an exemplary embodiment, the floor assembly may be used as a sports floor assembly. The sports floor assembly 10 has a layered structure. The sports floor assembly 100 may comprise several layers stacked on top of one another in a vertical direction Z. The top of the sports floor assembly is provided by a translucent surface panel 100. The translucent surface panel 100 is arranged on top of an array 200 of display devices. The display devices may be mounted on an elastic support structure 300. A rigid substructure 400 may form at the bottom of the sports floor assembly 100.

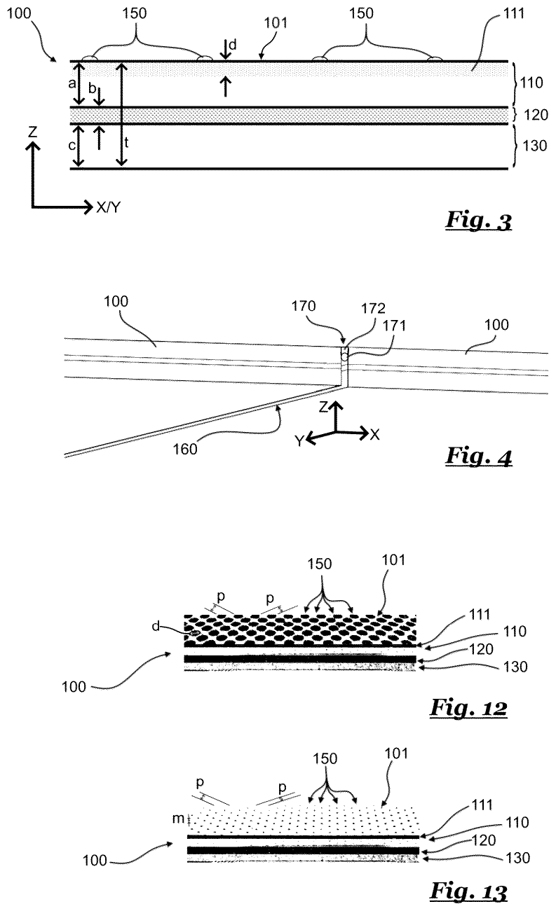

The translucent surface panel 100 may comprise multiple panel layers. For example, the surface panel 100 may consist of a cover layer 110, and intermediate layer 120 and a base layer 130. The intermediate layer 120 may be sandwiched between the cover layer 110 and the base layer 130. In order to render the surface panel 100 optically translucent, it may comprise a light diffusion layer 111. The light diffusion layer 111 may be integrated the cover layer 110, as shown in FIGS. 1 and 3, alternatively, or additionally, the intermediate layer 120 or the base layer 130 may include or light diffusion layer 111.

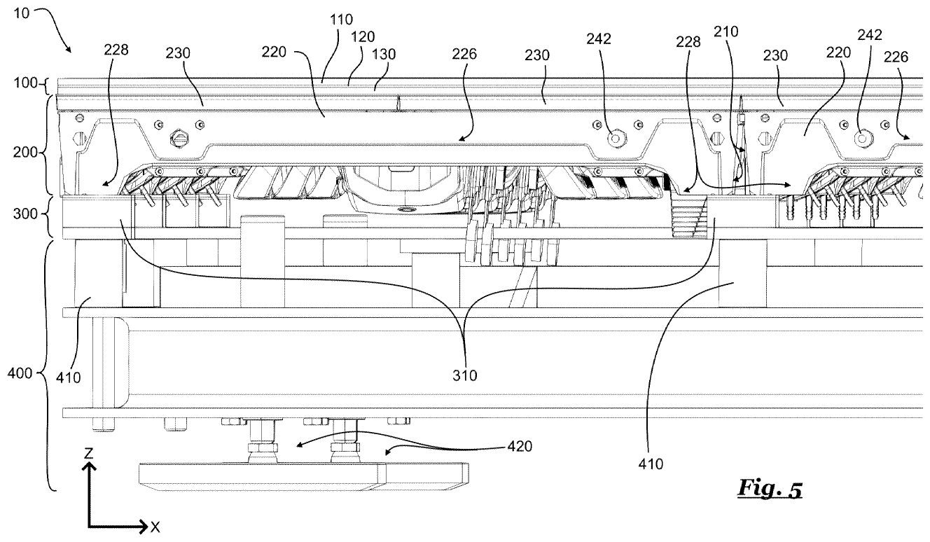

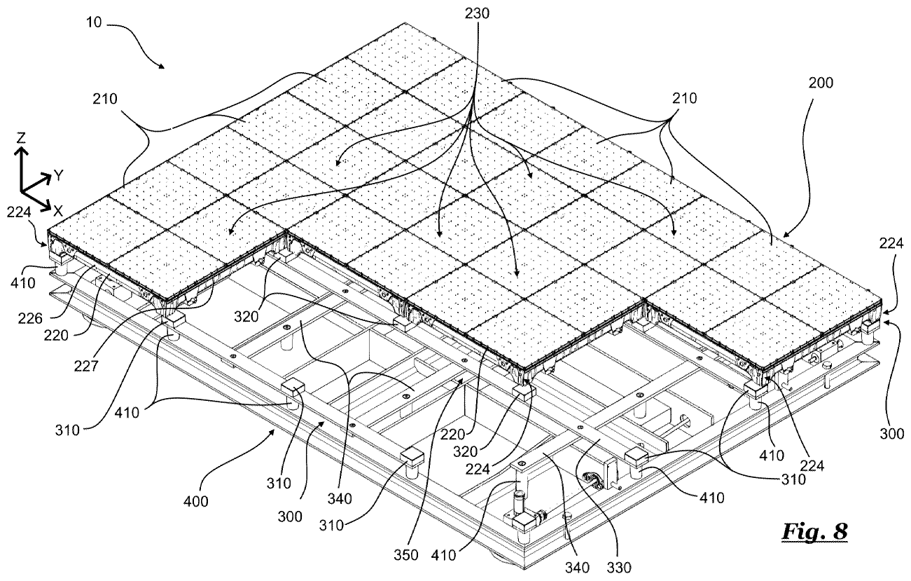

The array 200 of display devices, which is explained in further detail with respect to FIGS. 5 and 8, comprises a plurality of display devices facing upward in the vertical direction Z. The array 200 of display devices covered by the translucent surface panel 100. The translucent surface panel 100 and the display devices may in particular be adapted to one another such that the translucent surface panel 100 covers all of the display devices 210 of one array 200 completely. The sports floor assembly 10 may comprise an array 200 including several rows of display devices 210 and several columns of display devices 210. The sports floor assembly 10 shown in FIG. 8, for example, includes 15 display devices 210 joined together as one array 200. The exemplary embodiment shown in FIG. 8 shows the array 200 comprising three adjacent rows of display devices 210 arranged immediately adjacent one another in a first, lengthwise horizontal direction X. In the sports floor assembly 10 shown in FIG. 8 has an array 200 comprising four adjacent columns of display devices 210 arranged immediately adjacent one another in a second, crosswise horizontal direction Y.

The elastic support structure 300 may be provided below the translucent surface panel 100 and the array 200. The elastic support structure 300 may be configured to provide elastic properties to the sports floor assembly 10 in the vertical direction Z. The elastic support structure 300 mounts the array 200 display devices 210 of the sports floor assembly 10. As shown in FIG. 1 or 5, the translucent surface panel 100 rests directly on top of the array 200 of display devices 210. The elastic support structure 300 and the display devices may in particular be adapted to one another such that the elastic support structure 300 is entirely covered by the array 200. The elasticity of the elastic support structure 300 and the vertical direction Z may be substantially larger than the elasticity of the translucent surface panel 100 and the vertical direction and/or than the elasticity of the array 200 and the vertical direction Z.

In the illustrated embodiment of a sports floor assembly 10, the array 200 is vertically interposed between the translucent surface panel 100 and the elastic support structure 300.

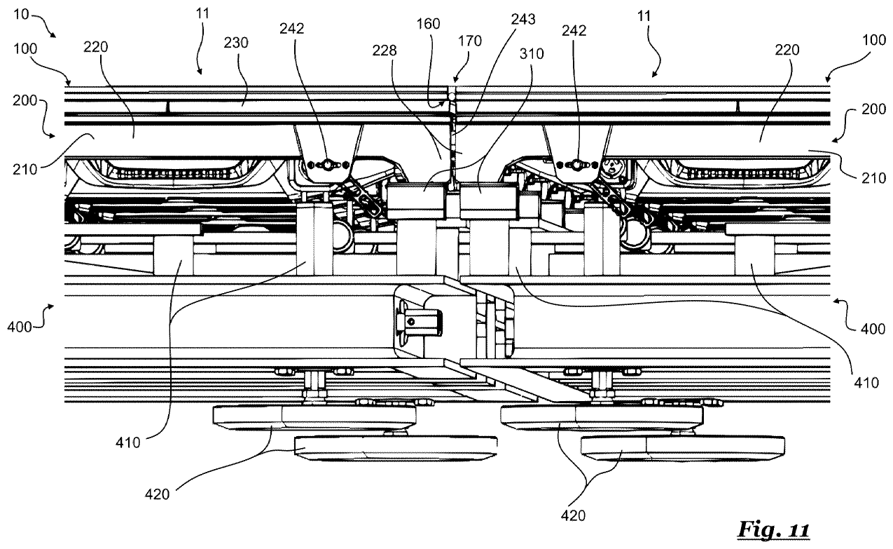

Furthermore, the sports floor assembly may be equipped with a rigid substructure 400. The rigid substructure is explained in further detail with respect to FIG. 8. The translucent surface panel 100, the array 200 and the elastic support structure 300 may be situated on top of the rigid substructure 400. The elastic support structure 300 has an elasticity in the vertical direction Z substantially larger than the elasticity of the rigid substructure 400 and the vertical direction Z. For example, the rigid substructure 400 may be realized as a framework made of metal sheets and/or molded metal parts. The rigid substructure 400 may comprise an integrally formed solid body. The rigid substructure 400 may be configured to be placed on a floor surface in a sports arena or generally an event location. The rigid substructure 400 may be provided with a plurality of legs 420, such as the legs 420 of embodiments shown in FIG. 5 or 11. For example four legs 420 may be arranged in four corners of a sports floor assembly 10 of cubic shape. One or more of the plurality of legs 420 may be height adjustable to accommodate for unevenness of the ground below the sports floor assembly 10.

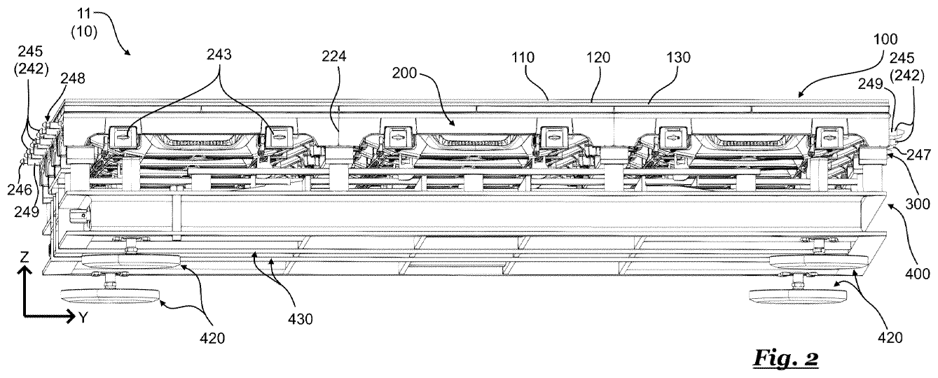

The sports floor assembly 10 may be designed to be assembled from a multitude of like or identical assembly units 11, such as shown in FIG. 2. Each assembly unit 11 may include one translucent surface panel 100, one array 200 of display devices, one elastic support structure 301 rigid substructure 400. The components of each assembly unit 11 may be dimensioned to fit below one another in the vertical direction Z in a substantially congruent manner. In the exemplary embodiment illustrated in the figures, the assembly unit 11 has a rectangular cross-section and the unit's components have the same rectangular cross-section.

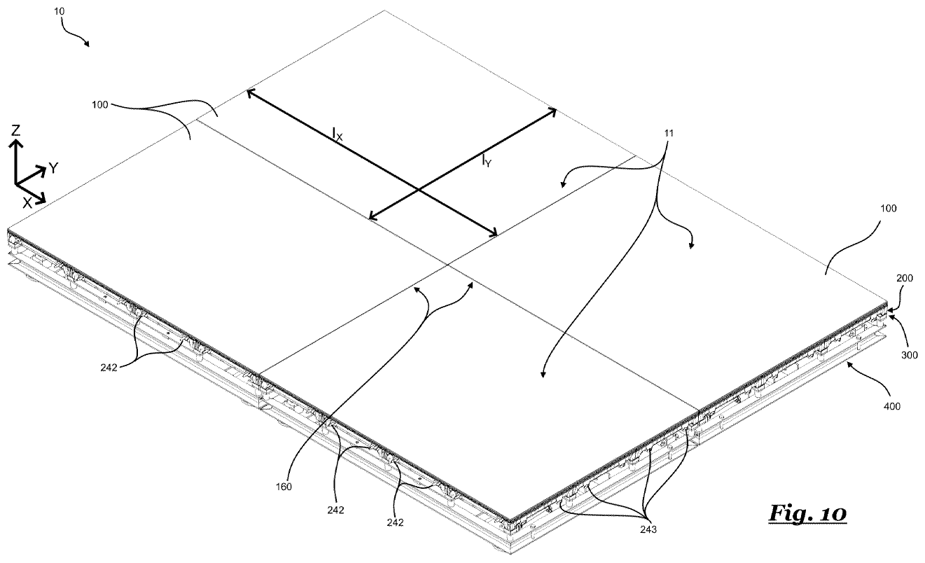

The exemplary assembly unit 11 has a unit length I_{X} in the first, lengthwise horizontal direction X of 2 m and a unit width I_{Y} in the second, crosswise horizontal direction Y of 1.5 m, indicated in FIG. 10. The length and width of the translucent surface panel 100 may correspond to the unit length and unit width. The length and width of the array 200 may correspond to the unit length and unit width. The length and width of the elastic support unit 300 may correspond to the unit length and unit width. The length and width of the substructure 400 may correspond to the unit length and unit width.

The sports floor assembly 10 or assembly unit 11 may be handled with conventional transportation means (e.g. a forklift) engaging the rigid substructure. The rigid substructure 400 may be configured to be contacted by transportation tools. For example, the rigid substructure 400 may be provided with receptions 430 for forks of a forklift.

FIGS. 3 and 4 show schematic illustrations of translucent surface panels 100. The translucent surface panels 100 may be made from one material or several materials. Translucent surface panels 100 may for example comprise or consist at least one polymer material, such polyvinyl butyral (PVB), ethylene-vinyl acetate (EVA), ionoplast polymers, cast in place (CIP) liquid resin, polymethylmethacrylate (PMMA, plexiglas) and/or thermoplastic polyurethane (TPU). Alternatively, or additionally, the translucent surface panel may comprise or consist of at least one glass material, in particular security glass according to EN 12150, in particular SGG securit®. For example, a translucent surface panel 100 may be realized as a composite glass panel 100, as described below. A glass panel may be particularly wear resistant.

FIG. 3 illustrates a composite glass floor panel 100 comprising several layers, such as a cover layer 110, a base layer 130 and an intermediate layer 120 interposed between the cover layer 110 and the base layer 130. The composite glass floor panel 100 extends in a planar manner in the first and second horizontal directions X, Y. The cover layer 110 is arranged above the intermediate layer 120 in the vertical direction Z. The intermediate layer 120 is arranged above the base layer 130 in the vertical direction Z. The cover layer 110 may be made of a first glass panel. The base layer 130 may be made of a second glass panel. The intermediate layer 120 may comprise or consist of at least one polymer film. The cover layer 110, the intermediate layer 120 the base layer 130 are sequentially laminated to form the composite glass panel 100. The intermediate layer 120 may in particular be a PVB-polymer film. The polymer intermediate layer 120 may be bonded between the cover layer 110 and the base layer 130 which may in particular be made of a glass material.

The composite glass floor panel 100 provides a walking surface for athletes. The walking surface is realized by the cover layer 110 of the panel. As shown in FIG. 2, the cover layer 110 of the sports floor assembly 10 has a top surface 101 exposed to the environment. Ceramic dots 150 or the like may be burned into the top surface 101 of the glass floor panel 100 to improve grip.

Schematic perspective views from an elevated point of view of glass floor panels 100 with differently sized dots 150 are shown in FIGS. 12 and 13. The dots may be of a small average diameter m and scattered apart so as not to impair the optical appearance of the sports floor assembly 10. The average dot diameter m may in particular be 10 mm or less.

In the example shown in FIG. 12, the dot size is 5 mm and the horizontal distance between adjacent dots 150 is slightly larger than the average diameter m of the dots 150. In the embodiment shown in FIG. 12, the horizontal distance is defined as a regular pitch p of 6.4 mm. In further embodiments, the average dot diameter may for example be 2.5 mm, 3 mm or 3.5 mm.

In the example shown in FIG. 13, the dot size is 0.8 mm and the horizontal distance between adjacent dots 150 is much larger than the average diameter m of the dots 150. In the embodiment shown in FIG. 13, the horizontal distance is defined as a regular pitch p of 6.4 mm.

Alternatively, it is conceivable that the dots 150 may be spaced apart so far that the person walking on the sports floor assembly 10 touches several of the dots 150. For example, the distance between two adjacent dots 150 may be approximately 2.5 cm or approximately 1.25 cm.

In an exemplary embodiment, the dots 150 may be arranged in a regular pattern on the top surface 101 of the floor assembly 10. Such a pattern may have a constant dot diameter m and the same dot pitch p in two perpendicular horizontal directions. The sports floor assembly 10 may be configured to have a slip resistance value (linear friction coefficient) in the range of 88 to 98. The friction coefficient may be determined using a CEN rubber under dry conditions at a temperature of 23±2° C. (in particular in accordance to the method defined in EN 13036-4:2011).

The composite glass floor panel 100 has a panel thickness t defined in the vertical direction Z. The panel thickness t may be in the range of 10 mm to 13 mm, in particular in the range 11 mm to 12 mm. The cover layer 110 has a (cover layer) thickness a. The cover layer thickness a may be in the range of 4.5 mm to 5.5 mm, in particular 5 mm. The base layer 110 has a (base layer) thickness c. The base layer thickness c may be in the range of 4.5 mm to 5.5 mm, in particular 5 mm. In an exemplary embodiment, the thickness of the cover layer may be substantially equal to the thickness of the base layer. The thickness b of the intermediate layer 120 may be smaller than the thickness a of the cover layer 110 and/or smaller than the thickness c of the base layer 130. The thickness b of the intermediate layer may be between 1.0 mm and 2.0 mm, in particular 1.4 mm to 1.6 mm.

The composite glass floor panel 100 may be provided with a light diffusion layer 111. A light diffusion layer 111 may be provided to render the composite glass floor panel 100 opaque but light transmissive. In case a composite glass floor panel 100 provided with a light diffusion layer 111 is arranged on top of the upward facing displays devices 210 of the array 200, the panel 100 and in particular its light diffusion layer serve as a rear projection surface for the light emitted by the display devices to form an image at the top surface of the sports floor assembly 10.

A surface treatment may be performed on the cover layer 110 to form the light diffusion layer 111. The light diffusion layer 111 may be formed at the top surface of the cover layer 100 facing away from the display devices 210. The light diffusion layer 111 may extend into the composite glass floor panel 100 beginning at the top surface thereof. The cover layer 110 may be configured such that the light diffusion layer 111 extends only partially through part of the cover layer 110 in the vertical direction Z. The light diffusion layer 111 may have a thickness d smaller than the cover layer thickness a. The diffusion layer thickness d may be no larger than 2 mm, in particular no larger than 1 mm or no larger than 100 μm. The cover layer 110 may for example be modified by acid etching to form the light diffusion layer 111 therein. In an exemplary embodiment, the light diffusion layer 111 may extend (e.g., continuously) over the entire top surface of the composite glass floor 100 in the first and second horizontal direction. The translucent surface panel, in particular the composite glass floor panel 100, may be provided with a matte surface finish. The panel may have a mirror gloss of less than 7%, in particular according to EN ISO 2813. The panel may have a light reflection rate in the range of 0.05 to 0.07, in particular according to EN 410 and/or EN 13745.

The composite glass floor panel 100 may have a light transmission in the range of 40% to 95%. In some embodiments of a sports floor assembly 10, the light transmission through the composite glass floor assembly 100 in the vertical direction Z may be 70% to 90%. The light transmission of the glass floor panel 100 may in particular be configured to be 86±1%. A sports floor assembly having such a high light transmission rate may be preferred in some applications where particularly bright or brilliant images are desired.

Alternatively, the composite glass floor panel 100 may in some embodiments have a light transmission through the composite glass floor assembly 100 in the vertical direction Z in the range of 40% to 60%. The light transmission rate of the glass floor assembly 100 may be reduced. The light transmission of the glass floor panel 100 may in particular be in the range of 50% to 52%. The light transmission may in some embodiments be configured to be 51±0.5%. The light transmission (TL) may in particular be calculated in accordance with DIN EN 410 (2011-04) (DIN EN 41″, “Glass in building—Determination of luminous and solar characteristics of glazing”, Deutsches Institut für Normung e. V. (DIN), April 2011) or CIE (15-2004) (CIE 15: “Technical Report: Colorimetry”, 3rd edition, International Commission on Illumination (CIE), 2004). By configuring the composite glass floor panel 100 with a low light transmission of 60% or less, it is possible to display images of particularly high contrast with the sports floor assembly 10 according to the present disclosure. By configuring the light transmission in the described range, a high image quality can be achieved even for images including dark colors or even black appearance. However, it is advantageous to avoid configuring the light transmission with a low value below the range described hereinabove because otherwise colors may be perceived as dull or washed-out, or the overall image may appear too dark.

The composite glass floor panel 100 may use the intermediate layer 120 to define the overall light transmission rate. I.e., the cover layer and/or the base layer may have a larger light transmission than the intermediate layer. The light transmission rate of the intermediate layer 120 may be in the range of 45% to 55%, or, in particular, in the range of 50% to 52%. The light transmission rate of the intermediate layer 120 may be determined by addition of a colorant to the polymer film used in the intermediate layer 120.

FIG. 4 shows a schematic view of a pair of glass floor panels 100 arranged immediately adjacent to one another in the lengthwise direction X from a lowered point of view. A gap 160 is formed between the floor panels 100. The gap 160 extends in the crosswise direction Y. The gap 160 may have a gap width of 2 mm. The gap width may be constant in the crosswise direction Y along the entire length of the panels 100 adjacent to the gap. A gap 160 may be provided to avoid pairs of immediately adjacent panels 100 from colliding.

A sealing member 170 may be provided inside of the gap 160. The sealing member 170 may include a sealing cord 171. Additionally, or alternatively, the sealing member 170 may include an elastic adhesive 172. The elastic adhesive may in particular be a two-component silicone cured inside of the gap 160. The sealing member 170 renders the top surface of the sports floor assembly 10 smooth and protects the layers below the composite glass floor panel 100 from water and dirt from the playing field. The sealing member 170 forms a mechanical barrier between adjacent floor panels to avoid a glass-glass interface. The sealing member 170 may be optically clear. An optically clear sealing member 170 may in particular be have a larger light transmission rate than all of the directly adjacent panels.

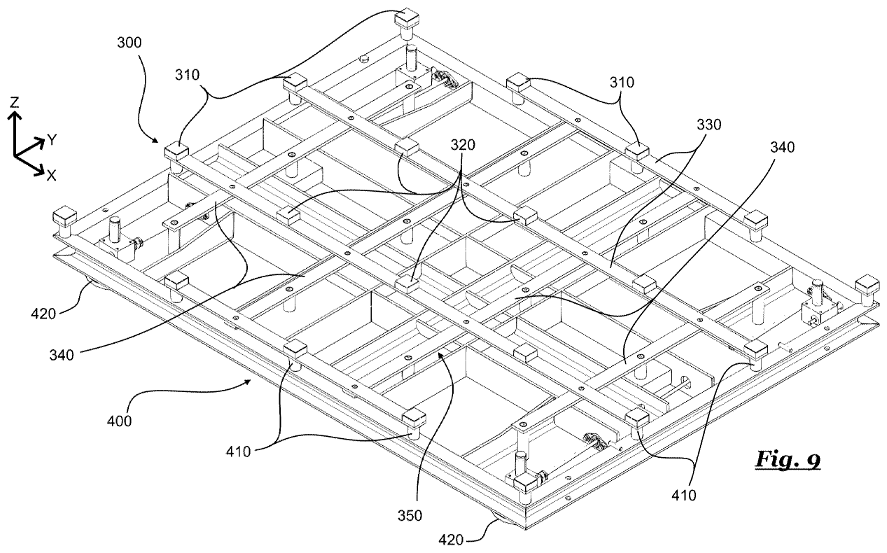

FIG. 5 shows a partial side view of the sports floor assembly 10. FIG. 8 shows a perspective view of the sports floor assembly 10 in which the glass floor panel and some of the display devices 210 of the array 200 are not shown to allow a better understanding of the structure of the sports floor assembly. FIG. 9 shows a perspective view illustrating only the elastic support structure 300 and the rigid substructure 400 of a sports floor assembly according to some embodiments of the present disclosure.

In FIG. 5, the array 200 of display devices 210 is arranged in the vertical direction Z on top of the elastic support structure 300 which, in turn is carried by the rigid substructure 400. The composite glass floor panel 100 rests directly on top of the display units 230 of the display devices 210. The display units 230 are shown in further detail in FIG. 8. The display units 230 are arranged to form a level surface extending in the first and second horizontal directions X, Y.

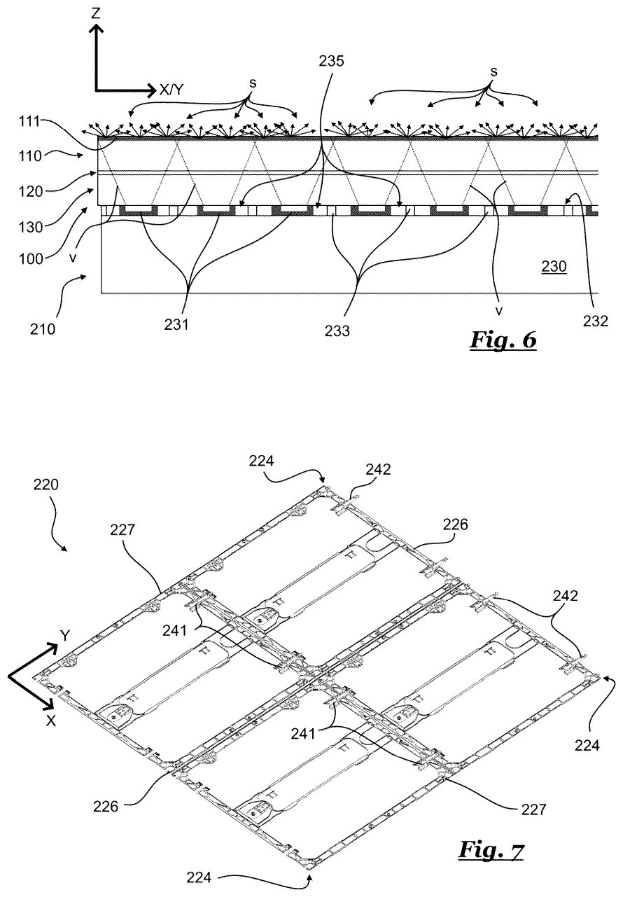

The display device 210 may in particular be realized as an LED display device such as schematically illustrated in FIG. 6. The display devices may comprise LED display units 230 having a flat panel surface 232 on which individual light emitting diodes (LEDs) 231 may be arranged in grooves or similar retractions 235. The individual LEDs 231 of an LED display unit 230 may be set back from its flat panel surface 232 in a downward vertical direction Z. Protrusions 233, such as pillars, dam-like protrusions or wall-like protrusions, may be interposed between a plurality of individual LEDs 231. The LEDs 231 may thus be arranged in grooves or similar retractions 235, below the surface level of the display unit 230 defined by the protrusions 233. By using a translucent panel 100 disposed above the display devices 210, the light from different adjacent LEDs 231 of the display device 210 is scattered before being emitted from the sports floor assembly 10. This allows to obfuscate shadows caused by the protrusions 233 and to prevent the appearance of a moiré effect.

The LEDs 231 emit light which travels through the translucent surface panel, which may in particular be a composite glass floor panel 100. The LEDs 231 create light-cones indicated in dotted lines shown in FIG. 6. Adjacent LEDs 231 may create light cones v overlapping within the translucent surface panel 100, in particular in the cover layer 110, more particularly in the light diffusion layer 111. The LED device 230 and the panel 100 may be adapted to ascertain that light cones v from adjacent LEDs 231 overlap within the panel 100, in particular at the level of the light diffusion layer 111 or below the light diffusion layer in the vertical direction Z. The light diffusion layer 111 is configured to cause light diffusion (i.e. scattering of light). As the composite glass floor panel 100 scatters the light s it may act as a rear projection surface for the underlying LEDs 231. The light s from the LEDs 231 leaving the panel 100 is scattered. The composite glass floor panel 100 is configured to transform light from small or even dot shaped light sources such as LEDs 231 into scattered light s (diffused light). Diffused light is light that has an even concentration across the spread of its beam (i.e. “soft light”).

The display units 230 carried by respective box structures 220. A vertical cross-section of a box structure 220 is illustrated in detail in FIG. 7. Each display device 210 may comprise a box structure 220. Each box structure 220 may hold a respective display device. In some embodiments, an array 200 of box structures 220 may be provided without a display unit 230. The box structure 220 realizes rigid frame in particular for the individual display devices 210. The box structure 220 may be made of a metal material, such as aluminum or steel. In the embodiment illustrated in the figures, the box structure 220 is of a generally square shape. The display devices 210 including a flat panel display unit 230 supported by a box structure 220 may in particular be configured according to CN 108 682 320 A or CN 219 536 489 U.

Each box structure 220 is delimited by first beams 226 extending in the first horizontal direction X and second beams 227 extending in the second horizontal direction Y. The first and second beams 226, 227 are joined at the four corners 224 of the box structure 220, for example by welding. The beams 226, 227 form a square box frame. The box structure 220 is provided with the respective foot 228 in each corner 224 of the box structure. The feet 228 of the box structure 220 extends downwards in the vertical direction Z. Only the feet 228 of the display devices 210 are in contacting engagement with the elastic support structure 300. The feet 228 at the corners 224 of the display devices 210 may stand on pads 310, 320 of the elastic support structure 300, as shown in FIGS. 5 and 8.

FIG. 11 shows how box structures 220 may be interlocked so as to form an array 200 of box structures. As shown in the illustrated embodiments, the box structures 220 may each contain a display unit or part of a display unit. Alternatively, an array of box structures 220 may be provided which do not contain display units. A box structure may for example contain a panel support unit (not shown) having a flat panel surface 232 in which a composite glass floor 100 may be arranged. Referring to FIG. 6, such a panel support surface could for example be made as a support free of LEDs for supporting the composite glass panel 100.

The skilled person understands that, while assembly units 11 including a respective composite glass panel 100, and a respective array 200, as well as possibly a respective elastic support structure 300 and/or a respective rigid substructure 400 may be used, in one or more embodiments, the layered structure may not have a 1:1(:1:1) association thereof. For example, the composite glass floor panels 100 of a format (width×length) may differ from the format of the underlying array 200 and/or elastic support structure 300. In an exemplary embodiment, one or more glass panels 100 may not be aligned with the underlying array 200. One or more glass panels 100 may be offset in a first and/or second horizontal direction X, Y with respect to the underlying array 200. Conversely, an elastic support structure 300 and/or rigid substructure 400 may be dimensioned in relation to the composite glass floor panels 100 such that one respective elastic support structure 300 and/or rigid substructure 400 carries a plurality of composite glass floor panels 100. For instance, a rigid substructure 400 and corresponding elastic support structure 300 may be dimensioned appropriately to extend over an entire playing field and carry several rows and columns of horizontally adjacent composite glass panels 100. In an exemplary embodiment, the array 200 of box structures 220 and/or display devices 210 may be interlocked in the first and/or second horizontal direction X, Y to evenly distribute mechanical loads.

The box structures 220 in the array 200 may be spliced together using connection members 241 configured to releasably connect the box structures 220 of adjacent display devices 210. Additionally, or alternatively, box structures 220 of neighboring assembly units 11 may be spliced together using connection members 242, 243, as shown for example in FIG. 11. Connection members 241, 242, 243 may for example include bolts adapted to be insertable into corresponding receptions of the box structures 220 in order to anchor a first box structure 220 in a directly adjacent second box structure 220. The receptions for the connection members 241, 242, 243 may be provided in the first and/or second beams 226, 227 of the box structure 220. Connection members 241, 242, 243 and receptions for rigidly connecting the box structures 220 of adjacent display devices 210 to one another may in particular be configured according to on CN 108 682 320 A or CN 219 536 489 U.

The connection members 242, 243 which are configured to connect adjacent arrays 200 may be pins 245, such as shown in FIG. 2. The pins 245 may be configured to have a first end 246 configured to be anchored within a first array and a second end 247 configured to be inserted into a reception of a second array. The pin 245 may have a generally cylindrical shape. The pin may extent in an axial direction from its second end 247 to its first end 246. The second end 247 of the pin may be tapered. The second end 247 of the pin may for example be conical and/or hemispherical. The first end 246 of the pin may have at least one radial feature, such as a groove, in particular an annular groove 248, or a protrusion, configured to engage a corresponding stop of the reception. The radial feature of the pin 245 and the corresponding stop of the first array may be configured to firmly attach the pin 245 to the first array. The engagement of the pin 245 to the first array may configured to be selectively releasable. The pin 245 may have a middle section 249 between the first end 246 and the second end 247 having a substantially constant cross section. The middle section 249 of the pin 245 may have a constant circular cross section. The middle section 249 of the pin 245 may be configured to fittingly engage the reception of the second array. The middle section 249 of the pin may be configured to engage the reception in a form-fitting manner in the vertical direction Z. The middle section of the pin may be optionally be configured to engage the reception in a form-fitting manner in the first or second horizontal direction X or Y perpendicular with respect to the pin axis.

The box structure 220 mechanically supports the display units 230. The weight of the composite glass floor panels 100 and any object or person thereon is borne by the box structure 220. Forces and impacts affecting the sports floor assembly 10 in the vertical direction Z are transferred from the composite glass floor panel 100 through the box structure 220 to the elastic support structure 300. The box structure 220 relieves the display unit 230 from a mechanical stress in the first and second horizontal directions X, Y. By splicing the multitude of box structures 220 of an array 200 of display devices 210 together, loads acting locally above one display device 210 are transferred to the adjacent display devices 210. Loads acting on onto one display device 210 are thus dispersed through the box structures 220 in the sports floor assembly 10. Peak loads due to impacts or the like are dispersed throughout the composite glass floor panel 100 and the box structures 220 which renders the sports floor assembly 10 particularly resilient. The sports floor assembly 10 may have an area-elastic vertical deformation value in the range of 1 mm to 4 mm, in particular in the range of 1.5 mm to 3.5 mm. The deformation may be determined in millimeters under a standard load of 1500 N, in particular according to EN 14809 (DIN EN 14809; “Surfaces for sports areas-Determination of vertical deformation—Corrigendum 1”, Deutsches Institut für Normung e. V.; Deutsches Institut für Normung e. V. (DIN), April 2008).

FIG. 8 illustrates the arrangement of the plurality of display devices 210 on the elastic support structure 300. The array 200 rests directly on top of the elastic support structure 300. The elastic support structure 300 may comprise support pads 310, 320 and beam-like spring members 330, 340. The feet 228 at the corners 224 of the box structures 220 stand on the support pads 310, 320. The box structures 220 may thus be suspended by the support pads 310, 320 of the elastic support structure 300.

The first group of support pads 310 may be arranged below the outer edges of the composite glass floor panel 100. A first group of support pads 310 may be arranged along the outer circumference of an assembly unit 11. A first group of support pads 310 may be arranged directly above pillars 410 of the rigid substructure 400.

A second group of support pads 320 may be arranged within the area stand by the glass floor panel 100 and distanced from its edges. A second group of support pads 320 may be arranged in a central area of an assembly unit 11. A second group of support pads 320 may be arranged offset from the pillars 410 of the rigid substructure 400 and the first and/or second horizontal direction X, Y. Beam-like spring members 330, 340 may attach the second group of support pads 320 to the rigid substructure.

Each second support pad 320 may be arranged to carry the four corners 224 of four directly adjoining display devices 210 in a central region of the sports floor assembly 10. The first support pads 310 may be arranged along the outer circumference of the sports floor assembly 10 or an assembly unit 11. First support pads 310 arranged at the outer corners of an assembly unit 11 or sports floor assembly 10 may be configured to carry only one corner 224 of one single display unit 210. First support pads 310 arranged along the edge of an assembly unit 11 or sports floor assembly 10 may be configured to support the two corners 224 of one respective pair of directly adjacent display units 210. The first support pads 310 may be configured to be more elastic than the second support pads 320. The second support pads 320 may for example made of a substantially rigid polymer material, such as polyurethane. The first support pads 310 may be made of an elastic polymer material, such as Regupol®.

FIG. 9 allows a clear view of the elastic support structure 300 mounted on top of the rigid substructure 400. The beam-like spring members 330, 340 may be supported by pillars 410 of the rigid substructure 400. The rigid substructure 400 may be a substantially hollow framework made of a rigid material, such as cast aluminum. The rigid substructure 400 may comprise a plurality of pillars 410 with a generally vertical extension. The pillars 410 may protrude upward from the rigid substructure 400 and the vertical direction Z. F

First support pads 310 may be arranged directly on top of the pillars 410. Beam-like spring members 330, 340 may be attached directly on top of the pillars 410. First beam-like spring members 330 extend into the first (lengthwise) horizontal direction X. Second beam-like spring members 340 extend into the second (crosswise) horizontal direction Y. Each beam-like spring member 330, 340 may be supported by at least one pillar 410, such as two or more pillars 410.

The elastic support structure 300 may include a mesh 350 of beam-like spring members 330, 340. The plurality of first beam-like spring members 330, which are oriented in the lengthwise direction X, and the plurality second beam-like spring members 340, which are oriented in the crosswise direction Y, form a corresponding plurality of intersections, thereby forming a mesh 350. A sports floor assembly 10 may include a plurality of first beam-like spring members 330 extending parallelly in the first horizontal direction X. Additionally, the sports floor assembly 10 may include a plurality of second beam-like spring members 340 extending parallelly in the second horizontal direction Y. The assembly unit 11 illustrated in FIG. 9, for example, includes four first beam-like spring members 330 and four beam-like second spring members 340, spread out evenly above the rigid support structure 400. At the intersection of first and second beam-like spring members 330, 340 rivets or similar connection means are provided to rigidly attached the first and second beam-like spring members 330, 340 two one another. The second support pads 320 may be suspended above the rigid substructure 400 via the mesh 350 of beam-like spring members 330, 340. All of the first beam-like spring members 330 may be arranged above the second beam-like spring members 340.

The elastic support structure 300 provides the sports floor assembly 10 with excellent mechanical properties. The sports floor assembly 10 may have a ball rebound value 93% or more. The ball rebound value may be determined by releasing a basketball from 1.8 m above the sports floor assembly, in comparison to a reference rebound value of said basketball on concrete (in particular in accordance to the method defined in EN 12235:2013). Additionally, or alternatively, the sports floor assembly may have an area-elastic force reduction value in the range of 45% to 55%. The force reduction value may be determined in accordance with EN 14808 (DIN EN 14904:2006; DIN EN 14808, “Surfaces for sports areas—Determination of shock absorption”, Deutsches Institut für Normung e. V.; Deutsches Institut für Normung e. V. (DIN), March 2006; DIN EN 14904:2006, “Sportböden—Mehrzweck-Sporthallenböden”, Deutsches Institut für Normung e. V. (DIN), June 2006).

FIG. 10 shows a perspective view of sports floor assembly 10 including multiple assembly units 11 and FIG. 11 shows a detailed side view of a pair of assembly units 11. The simplified illustration of FIG. 10 shows a sports floor assembly 10 consisting of two rows and two columns of assembly units 11. The skilled person understands that the number of adjacent assembly units the first horizontal direction X and/or in the second horizontal direction Y may be selected appropriately to cover a desired area to form a basketball playing field or the like. In an exemplary embodiment, the assembly units 11 of the sports floor assembly 10 may be of identical design. This allows to simplify maintenance as well as assembly and disassembly of a sports floor. Each assembly unit 11 has a unit length I_{X} and a unit width I_{Y}. The assembly units 11 a provided with connection members 242, 243 fully attachment of pairs of immediately adjacent units 11 to one another. In an exemplary embodiment, the assembly units 11 may be configured to be connected to one another exclusively in the layer of the array 200 of display devices 210.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

### EXAMPLES

The following section contains example embodiments of the disclosure.
Example 1. A floor assembly, in particular a sports floor assembly, comprising an elastic support structure; an array of display devices mounted on the elastic support structure; and a translucent surface panel covering the array and supported by the array.
Example 2. The floor assembly according to example 1, wherein the array is interposed between the translucent surface panel and the elastic support structure.
Example 3. The floor assembly according to example 1 or 2, wherein the translucent surface panel rests directly on the array of display devices.
Example 4. The floor assembly according to one of the preceding examples, wherein the display devices include a respective box structure.
Example 5. A floor assembly, in particular a sports floor assembly, in particular according to one of the preceding examples, comprising an elastic support structure; an array of interlocked box structures mounted on the elastic support structure; and a translucent surface panel covering the array and supported by the array.
Example 6. The floor assembly according to example 4 or 5, wherein the array is spliced together using connecting members configured to releasably connect adjacent box structures.
Example 7. The floor assembly according to one of the preceding examples 4, 5 or 6, wherein the elastic support structure comprises a plurality of support pads (310, 320) arranged below the array to carry the box structures.
Example 8. The floor assembly according to example 7, wherein each support pad is arranged at at least one of the edges and the corner of a box structure.
Example 9. The floor assembly according to example 7 or 8, wherein a first group of support pads is arranged below the corners of four adjacent box structures.
Example 10. The floor assembly according to one of the preceding examples 7 to 9, wherein a second group of support pads is arranged along the circumference of the floor assembly below the edges of two adjacent box structures.
Example 11. The floor assembly according to one of the preceding examples 7 to 10, wherein the elastic support structure includes first support pads which are elastic.
Example 12. The floor assembly according to one of the preceding examples 7 to 11, wherein the elastic support structure includes second pads which are rigid.
Example 13. The floor assembly according to example 12, wherein the elastic support structure comprises a plurality of beam-like spring members.
Example 14. The floor assembly according to example 13, wherein the plurality of beam-like spring members comprises a first set of spring members extending in a first horizontal direction (X) and a second set of spring members extending in a second horizontal direction (Y).
Example 15. The floor assembly according to example 13 or 14, wherein the plurality of beam-like spring members forms a mesh of interconnected beam-like spring members.
Example 16. The floor assembly according to one of the preceding examples, further comprising a rigid substructure on which the elastic support structure is suspended.
Example 17. The floor assembly according to example 16, wherein the substructure includes a plurality of pillars, and wherein the elastic support structure rests on the pillars.
Example 18. The floor assembly according to one of the preceding examples, wherein the translucent surface panel comprises or consists of a composite glass panel comprising a cover layer made of a glass panel; a base layer made of a glass panel; and intermediate layer made of at least one polymer film, wherein the cover layer, the intermediate layer and the base layer are sequentially laminated.
Example 19. The floor assembly according to one of the preceding examples, comprising a plurality of assembly units each comprising a respective elastic support structure, a respective array of display devices mounted on the elastic support structure; and a respective translucent surface panel, wherein the assembly units are arranged in rows and columns.
Example 20. The floor assembly according to example 19, wherein each assembly unit further comprises a respective rigid substructure, wherein one translucent surface panel, in particular one glass floor panel, is associated with the respective rigid substructure.
Example 21. The floor assembly according to example 22, wherein each assembly unit comprises a respective array of display devices covered by the translucent surface panel and sandwiched between the translucent surface panel and the rigid substructure.
Example 22. The floor assembly according to one of the preceding examples 19 to 21, wherein the plurality of assembly units is arranged to form pairs of adjacent translucent surface panels, wherein a gap is defined between each pair of adjacent translucent surface panels.
Example 23. The floor assembly according to example 22, wherein the plurality of assembly units is attached to each other.
Example 24. The floor assembly according to example 23, wherein the arrays of adjacent assembly units are spliced together using connecting members.
Example 25. The floor assembly according to one of the preceding examples, wherein the translucent surface panel has a light reflection rate in the range of 0.03 to 0.10, in particular in the range of 0.04 to 0.08, preferably in the range of 0.05 to 0.07
Example 26. The floor assembly according to one of the preceding examples, wherein the translucent surface panel has a mirror gloss of less than 15%, in particular less than 10%, preferably in the range of 3% to 7%, more preferably in the range 4% to 6%.
Example 27. The floor assembly according to one of the preceding examples, wherein the translucent surface panel has a slip resistance value in the range of 85 to 105, in particular in the range of 85 to 100, preferably in the range of 88 to 98.
Example 28. The floor assembly according to one of the preceding examples, wherein the floor assembly has a ball rebound value of at least 90%, in particular at least 93%, preferably at least 95%
Example 29. The floor assembly according to one of the preceding examples, wherein the floor assembly has an area-elastic vertical deformation value in the range of 1 mm to 4 mm, in particular in the range of 1.5 mm to 3.5 mm.
Example 30. The floor assembly according to one of the preceding examples, wherein the floor assembly has an area-elastic force reduction value in the range of 40% to 60%, in particular in the range 45% to 55%.

### LIST OF REFERENCE NUMERALS

10 sports floor assembly
11 assembly unit
100 composite glass floor panel/translucent surface panel
101 top surface
110 cover layer
111 diffusion layer
120 intermediate layer
130 base layer
150 dots
160 gap
170 sealing member
171 sealing cord
172 elastic adhesive
200 array of display devices
210 display device
220 box structure
224 box structure corner
226 first beam
227 second beam
228 foot
230 display unit
231 LED
232 flat panel surface
233 protrusion
235 retraction
241 connecting member
242 connecting member
243 connecting member
245 pin
246 first end
247 second end
248 feature
249 middle section
300 support structure
310 support pad
320 support pad
330 spring member
340 spring member
350 mesh
400 substructure
410 pillar
420 leg
430 recess
X first (lengthwise) horizontal direction
Y second (crosswise) horizontal direction
Z vertical direction
a thickness (cover layer)
b thickness (intermediate layer)
C thickness (base layer)
d thickness (light diffusing layer)
I_{X} unit length
I_{Y} unit width
m average diameter
p dot pitch
S scattered light
t thickness (panel)
V light cone

1. A floor assembly, comprising:
an elastic support structure;
an array of display devices mounted on the elastic support structure; and
a translucent surface panel covering the array and supported by the array.

2. The floor assembly according to claim 1, wherein the array is interposed between the translucent surface panel and the elastic support structure.

3. The floor assembly according to claim 1, wherein the translucent surface panel rests directly on the array of display devices.

4. The floor assembly according to claim 1, wherein the display devices include a respective box structure.

5. The floor assembly according to claim 4, wherein the array is spliced together using connecting members configured to releasably connect adjacent box structures.

6. The floor assembly according to claim 4, wherein the elastic support structure comprises a plurality of support pads arranged below the array to carry the box structures.

7. The floor assembly according to claim 1, wherein the floor assembly has an area-elastic vertical deformation value in a range of 1.5 mm to 3.5 mm.

8. The floor assembly according to claim 1, wherein the floor assembly has an area-elastic force reduction value in a range 45% to 55%.

9. The floor assembly according to claim 1, wherein the elastic support structure comprises a plurality of beam-like spring members comprising a first set of spring members extending in a first horizontal direction and a second set of spring members extending in a second horizontal direction different from the first horizontal direction.

10. The floor assembly according to claim 1, further comprising a rigid substructure on which the elastic support structure is suspended, wherein the rigid substructure includes a plurality of pillars, and wherein the elastic support structure rests on the pillars.

11. The floor assembly according to claim 1, wherein the translucent surface panel comprises a composite glass panel comprising:
a cover layer made of a glass panel;
a base layer made of a glass panel; and
intermediate layer made of at least one polymer film, wherein the cover layer, the intermediate layer, and the base layer are sequentially laminated.

12. The floor assembly according to claim 1, comprising a plurality of assembly units each comprising:
a respective elastic support structure,
a respective array of display devices mounted on the corresponding elastic support structure; and
a respective translucent surface panel, wherein the plurality of assembly units are arranged in rows and columns.

13. The floor assembly according to claim 12, wherein:
each assembly unit further comprises a respective rigid substructure, one of the translucent surface panels being associated with the respective rigid substructure, and
each assembly unit comprises a respective array covered by the translucent surface panel and sandwiched between the translucent surface panel and the rigid substructure.

14. The floor assembly according to claim 12, wherein the plurality of assembly units is arranged to form pairs of adjacent translucent surface panels, a gap being defined between each pair of adjacent translucent surface panels.

15. The floor assembly according to claim 14, wherein the arrays of adjacent assembly units are spliced together using connecting members.

16. A floor assembly, comprising:
an elastic support structure;
an array of interlocked box structures mounted on the elastic support structure; and
a translucent surface panel covering the array and supported by the array.

17. The floor assembly according to claim 16, wherein the array is spliced together using connecting members configured to releasably connect adjacent box structures.

18. The floor assembly according to claim 16, wherein the elastic support structure comprises a plurality of support pads arranged below the array to carry the box structures.

19. The floor assembly according to claim 18, wherein each support pad is arranged at at least one edge and corner of a box structure.

20. The floor assembly according to claim 18, wherein a group of the plurality of support pads is arranged below corners of four adjacent box structures.

21. The floor assembly according claim 18, wherein a group of the plurality of support pads is arranged along a circumference of the floor assembly below edges of two adjacent box structures.

22. The floor assembly according to claim 18, wherein the elastic support structure includes first support pads of the plurality of support pads which are elastic.

23. The floor assembly according to claim 18, wherein the elastic support structure includes second pads plurality of support pads which are rigid.

24. The floor assembly according to claim 16, wherein the elastic support structure comprises a plurality of beam-like spring members comprising a first set of spring members extending in a first horizontal direction and a second set of spring members extending in a second horizontal direction different from the first horizontal direction.

25. The floor assembly according to claim 24, wherein the plurality of beam-like spring members are configured to form a mesh of interconnected beam-like spring members.
